(19) United States
(12) Patent Application Publication
(10) Pub. No.: US 2009/0294789 A1
(43) Pub. Date: Dec. 3, 2009

(54) LIGHT EMITTING DEVICE AND METHOD OF MANUFACTURING LIGHT EMITTING DEVICE

(75) Inventor: Hiroshi Yoshida, Kanagawa (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: SONY CORPORATION, Tokyo (JP)

(21) Appl. No.: 12/470,744

(22) Filed: May 22, 2009

(30) Foreign Application Priority Data
May 27, 2008 (JP) 2008-137472

(51) Int. Cl. H01L 33/00; H01L 21/77

(52) U.S. Cl. 257/98; 438/27; 257/102; 257/E33.055; 257/E33.013; 438/28; 257/E21.598

(57) ABSTRACT

A light emitting device includes a light emitting element emitting light, a first substrate on which the light emitting element is mounted, a second substrate forming a sealing space for the light emitting element between the first substrate and the second substrate and a light exiting window for allowing light emitted from the light emitting element to exit, in which at least one of the first substrate and the second substrate has cleavage characteristics and a cleavage plane thereof serves as a window attaching surface to which the light exiting window is attached.

### BACKGROUND OF THE INVENTION

1. Field of the Invention

The present invention relates to a light emitting device and a method of manufacturing the light emitting device. Particularly, the invention relates to a light emitting device (semiconductor light emitting device) including a semiconductor light emitting element typified by a semiconductor laser and a method of manufacturing the same.

2. Description of the Related Art

A package of a semiconductor laser is commonly made of a metal material called as a CAN package. The size of the package for a light source of an optical disc was mainly 9 mm in diameter in 1980's, 5.6 mm in diameter in 1990's and is 3 mm in one edge in 2000's, which is made of a resin material called as a frame. In the present circumstances, further size reduction of the package is demanded. On the background thereof, there is a demand for a thinner and smaller optical disc device (recording/playback device) which uses the semiconductor laser as the light source.

In order to realize size reduction of the package on the light source side, measures for reliability reduction caused by heat generation of the light emitting element and measures for reliability reduction caused by sealing performance can be cited. That is, in a period when it was necessary to secure high sealing performance, size reduction from 9 mm to 5.6 mm has been realized. In order to realize the size reduction, measures have been devised in reduction of heat generation by reducing electric power and increase of tolerance due to processes and a configuration. Furthermore, due to improvement in quality of an end-face protection film, improvement of a technique for forming the end-face and so on, the reliability can be secured even when the sealing performance is not so high. According to this, a resin can be used as a material for the package, which realizes size reduction.

On the other hand, for example, in order to realize a high-density optical disc, there is a demand for a short wavelength in the light source. Therefore, in an application of a high-density Blu-ray disc, a light source having a short wavelength of 405 nm is used. In the light source in this wavelength band, high hermetic sealing performance is necessary for maintain characteristics. Therefore, the above frame package is not applied for the light source in the short-wavelength band. The frame package is applied for light sources in other wavelengths, for example, a light source in an intermediate-wavelength band of 650 nm which is applied to a DVD, because it is not necessary that hermetic sealing performance is so high as the light source in the short-wavelength band.

FIG. 15 is a sectional side view showing a configuration of a light emitting device in related art using a CAN package. A shown light emitting device 51 includes a light emitting element 54 sealed inside a cap member 53 bonded to a base member (stem) 52. The light emitting element 54 is formed by using a chip-state semiconductor laser element. The light emitting element 54 is mounted on a heatsink 56 through a submount 55 made of, for example, AlN (aluminium nitride). Plating (for example, gold plating) is performed on a surface of the heatsink 56.

A light exiting window 57 is provided at a direction in which light (laser light) is emitted from the light emitting element 54. The light exiting window 57 is bonded to the cap member 53 in a state of covering a hole 58 provided at a ceiling portion of the cap member 53. Additionally, plural lead pins 59 are attached to the base member 52. The light emitting element 54 is electrically connected to the lead pin 59 through a metal wire 60.

In the light emitting device 51 having the above configuration, light is emitted from an end face of the light emitting element 54. The light is emitted to the outside through the light exiting window 57. Therefore, a member of reflecting/refracting light does not exist between the light emitting element 54 and the light exiting window 57, and light is directly transmitted through the light exiting window 57. The light emitting device 51 having the above configuration is assembled by each light emitting device.

On the other hand, there also exist packages including not only metal and resin but also a lead frame, ceramic and the like for a substrate to which the light emitting element is connected. As a feature in the configuration, a fact that a member of reflecting light is arranged between the light emitting element and the light exiting window can be cited. As a feature in an assembly process, a fact that the light emitting element is connected to an aggregation of mounting substrates and the light exiting window is connected to the integrated body or a separated body is cited. That is, in a connecting process of the light emitting element included in the assembly process of the light emitting device, batch processing is performed, in which cost reduction is realized by increasing manufacturing efficiency. On the other hand, there is a disadvantage that costs for members are increased since it is necessary that an optical component for reflecting or refracting light is assembled inside the package. Concerning a joint between the light exiting window and a support portion which supports the light exiting window, a sealing resin is often used as an adhesive due to surface inaccuracy of a surface to which the light exiting window is attached (hereinafter, “window attaching surface”). Accordingly, the sealing resin is low in hermetic sealing performance as compared with the hermetic sealing applied in the CAN package.

As a configuration of the light emitting device which is advantageous for realizing size reduction (particularly, slimming) of the package, the configuration in which the light emitting element is mounted in a lateral posture on the support substrate so that an optical axis of the light emitting element is arranged in parallel with a principal surface of the support substrate on which the light emitting element is mounted directly or through a member such as a submount is well known (For example, refer to JP-5-129712 (Patent Document 1), JP-A-63-67794 (Patent Document 2) and JP-T-2004-527917 (Patent Document 3)).

### SUMMARY OF THE INVENTION

The CAN package which is mainstream in the optical disc application has a disadvantage in mass productivity in a point that the manufacturing method is not a batch method. Though the CAN package has an advantage that heat releasing performance and hermetic sealing performance after assembly can be secured, it is difficult to realize size reduction. On the other hand, a frame laser in which the substrate to which the light emitting element is connected is made of resin is suitable for realizing size reduction, but is inferior in the hermetic sealing performance because the material is resin.

In the light emitting device in which the light emitting element is mounted on the support substrate in the lateral posture, there was a problem that hermetic sealing performance is low due to surface inaccuracy of the window attaching surface. For example, in the case that solder is used as an adhesive when attaching the light exiting window, flatness of a soldering surface deteriorates due to effects of surface tension when the solder is melted because of the surface inaccuracy of the window attaching surface. Accordingly, unevenness in thickness occurs in a solder layer and a gap may be generated after the solder is solidified due to the unevenness. As a result, it is difficult to seal the light emitting element with high hermeticity. This point is the same as the case of using a resin adhesive instead of solder.

Additionally, as described in Patent Document 3, when the light exiting window is provided at a casing formed by a stacked body of ceramic, the surface accuracy of the window attaching surface is commonly 20 μm due to uneven solvent volatilization when the ceramic is sintered and uneven contraction caused by the shape. Furthermore, considering positioning accuracy in a stacking process, variations in size due to difference between solidification and contraction in respective layers and the like, it is assumed that the surface accuracy of the window attaching surface further deteriorates. Therefore, it is difficult to secure high hermetic sealing performance by using a solder glass and the like. First of all, since the stacking process is necessary, there is an disadvantage in points of deterioration of productivity and cost increase caused by increase of the number of processes.

A light emitting device according to an embodiment of the invention includes a light emitting element emitting light, a first substrate on which the light emitting element is mounted, a second substrate forming a sealing space for the light emitting element between the first substrate and the second substrate, and a light exiting window for allowing light emitted from the light emitting element to exit, in which at least one of the first substrate and a cleavage plane thereof serves as the second substrate has a cleavage characteristic and a window attaching surface to which the light exiting window is attached.

In the light emitting device according to the embodiment of the invention, the light emitting elements are mounted on the first substrate and the second substrate forms the sealing space between the first substrate and the second substrate, thereby realizing the size reduction of the package. Additionally, the window attaching surface to which the light exiting window is attached is the cleavage plane concerning at least one substrate, therefore, the surface accuracy (flatness) of the window attaching surface is increased. Accordingly, it is possible to seal the light emitting element with high hermeticity.

A method of manufacturing a light emitting device according to an embodiment of the invention includes the steps of mounting plural light emitting elements on a first substrate, forming plural concave portions on a second substrate so as to correspond to mounting positions of the plural light emitting elements to be mounted on the first substrate, bonding the first substrate to the second substrate so as to house the light emitting elements in the concave portions, cleaving at least one substrate in the first substrate and the second substrate and attaching a light exiting window on a cleavage plane of at least one substrate in a state of covering light guide holes opening at the cleavage plane.

In the method of manufacturing the light emitting device according to the embodiment of the invention, after the plural light emitting elements are mounted on the first substrate, the first substrate and the second substrate are bonded to each other so as to house the light emitting elements in the concave portions, thereby forming small packages. Additionally, after at least one substrate of the first substrate and the second substrate is cleft, the light exiting window is attached to the cleavage plane, thereby sealing the light emitting elements housed in the concave portions with high hermeticity.

According to the embodiments of the invention, the light emitting device in which the light emitting element is sealed with high hermeticity though it is a small package can be provided.

### BRIEF DESCRIPTION OF THE DRAWINGS

FIG. 1 is a sectional side view showing a configuration of a light emitting device according to a first embodiment of the invention;

FIG. 2 is a process flowchart showing a manufacturing procedure of the light emitting device according to the first embodiment of the invention;

FIG. 3A and FIG. 3B are views (No. 1) explaining manufacturing processes of the light emitting device according to the first embodiment of the invention;

FIG. 4A and FIG. 4B are views (No. 2) explaining manufacturing processes of the light emitting device according to the first embodiment of the invention;

FIG. 5A and FIG. 5B are views (No. 3) explaining manufacturing processes of the light emitting device according to the first embodiment of the invention;

FIG. 6A to FIG. 6C are views (No. 4) explaining manufacturing processes of the light emitting device according to the first embodiment of the invention;

FIG. 7A and FIG. 7B are views (No. 5) explaining manufacturing processes of the light emitting device according to the first embodiment of the invention;

FIG. 8 is a sectional side view showing a configuration of a light emitting device according to a second embodiment of the invention;

FIG. 9 is a process flowchart showing a manufacturing procedure of the light emitting device according to the second embodiment;

FIG. 10A and FIG. 10B are views (No. 1) explaining manufacturing processes of the light emitting device according to the second embodiment of the invention;

FIG. 11A and FIG. 11B are views (No. 2) explaining manufacturing processes of the light emitting device according to the second embodiment of the invention;

FIG. 12A and FIG. 12B are views (No. 3) explaining manufacturing processes of the light emitting device according to the second embodiment of the invention;

FIG. 13A and FIG. 13B are views (No. 4) explaining manufacturing processes of the light emitting device according to the second embodiment of the invention;

FIG. 14 is a sectional side view showing another configuration of a light emitting device according to an embodiment of the invention;

FIG. 15 is a sectional side view showing a configuration of a light emitting device of related art;

### DESCRIPTION OF THE PREFERRED EMBODIMENTS

Hereinafter, specific embodiments of the invention will be explained in detail with reference to the drawings. The technical range of the invention is not limited to embodiments described below and various modifications and alternations are included within the scope from which specific effects obtained by constituent features of the invention and combination thereof can be derived.

### First Embodiment

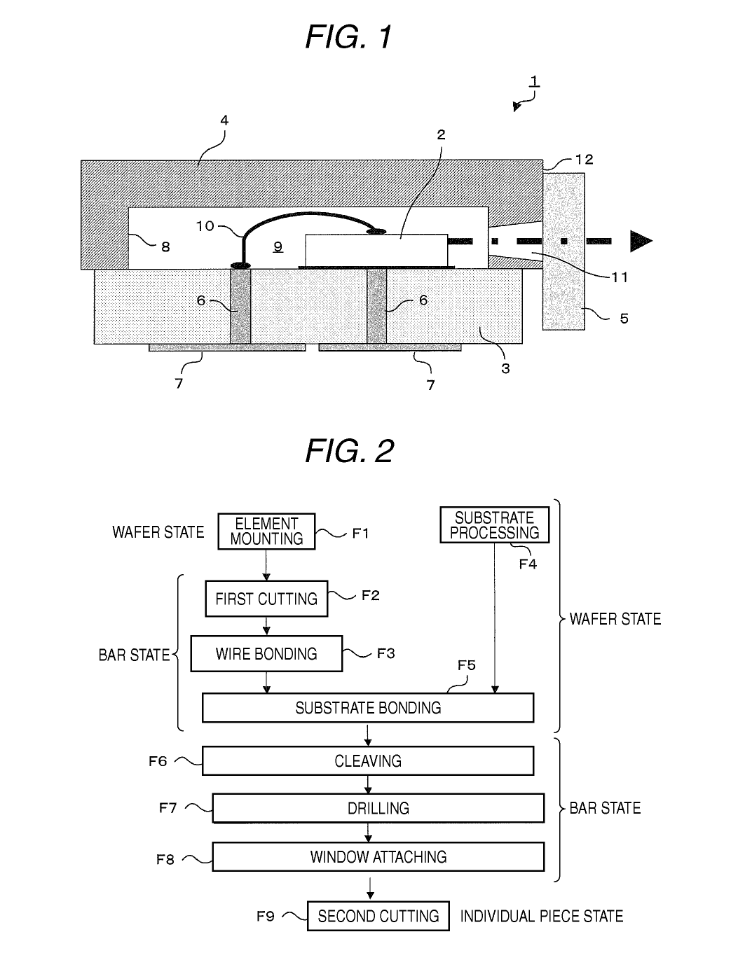

FIG. 1 is a sectional side view showing a configuration of a light emitting device according to a first embodiment of the invention. A shown light emitting device 1 largely includes a light emitting element 2, a first substrate 3, a second substrate 4 and a light exiting window 5.

The light emitting element 2 is formed by using, for example, a semiconductor light emitting element such as a semiconductor laser. In the light emitting element 2, light is emitted in a direction of an arrow (right direction) in the drawing. The light emitting element 2 is an element having light emitting wavelength of, for example, 450 nm or less, and particularly, when used as a light source for a Blu-ray disc, an element having a light emitting wavelength of 405 nm is used. Incidentally, in a light source for a DVD, an element having a light emitting wavelength of 650 nm is used. The light emitting element 2 is bonded to an upper surface of the first substrate 3 by using, for example, solder as an adhesive. However, it is not limited to this, and the light emitting element 2 may be bonded to the upper surface of the first substrate 3 by using a well-known wafer fusion method (wafer bonding method). The wafer fusion method is originally a bonding technique of integrating two wafers not using an adhesive and the like, however, it can be applied to not only bonding of wafers but also bonding between the light emitting element 2 and the first substrate 3. In the wafer fusion method, for example, after bonding surfaces of both to be bonding targets are cleaned (cleaning, removing an oxide film and the like), the bonding surfaces of both are touched each other and heat treatment is performed in this state to thereby bond the both tightly.

Incidentally, when the light emitting element 2 is bonded to the first substrate 3 by using solder as the adhesive, it is necessary that a solder material having higher melting point than a heating temperature in a heating process after that so as to prevent the adhesive material from being melted again in the heating process. On the other hand, when the light emitting element 2 is bonded to the first substrate 3 by using the wafer fusion method, the adhesive material is not interposed at the joint. Therefore, deterioration due to stress is reduced as well as the adhesive material is prevented from being melted again in the heating process after that, which will be desirable.

On the first substrate 3, the light emitting element 2 is mounted in a lateral posture. The “lateral posture” described here is a posture in which the optical axis of the light emitting element 2 is arranged in parallel with the principal surface (an upper surface or a lower surface) of the first substrate 3. The first substrate 3 is made of, for example, ceramic or metal. In the case of using ceramic for the first substrate 3 as well as high-heat releasing performance is necessary, it is desirable to use an AlN (aluminum nitride) ceramic for the first substrate 3. In the first substrate 3, vias (conduction paths) 6 piercing through the first substrate 3 in a plate thickness direction are provided. On an upper surface of the first substrate 3, bonding pads (not shown) having a three-layer structure including, for example, Ti (titanium), Ni (nickel) and Au (gold) are formed for the wire bonding which will be described later. On a surface of the first substrate 3 which is the opposite side of the surface to which the light emitting element 2 is attached, electrode portions 7 leading to the vias 6 are provided. Particularly, on the upper surface and the lower surface of the first substrate 3, the light emitting element 2 and the electrode portion 7 are arranged in the relationship of obverse-and-reverse. Therefore, it is possible to reduce the whole size of the light emitting device 1.

The second substrate 4 is formed by using a substrate having cleavage characteristics. In this case, the second substrate 4 is formed by a silicon substrate having cleavage characteristics as an example. The second substrate 4 has a concave portion 8 at the side facing the first substrate 3. The second substrate 4 forms a sealing space 9 of the light emitting element 2 between the first substrate 3 and the second substrate 4 by the existence of the concave portion 8. In the sealing space 9, the upper surface of the light emitting element 2 and the not-shown bonding pad are electrically connected through a wire 10 made of metal and the like.

The second substrate 4 has an outside dimension larger than the first substrate 3 when seen two-dimensionally. A light guide hole 11 is provided at the second substrate 4 in a state of being engaged in the concave portion 8. The light guide hole 11 is a hole for guiding light emitted from the light emitting element 2 to the outside. Therefore, the light guide hole 11 is provided at an emitting direction of light (on the optical axis) seen from the light emitting element 2 supported (mounted) on the first substrate 3. The light guide hole 11 is connecting to the sealing space 9 formed by the concave portion 8.

The light exiting window 5 is formed by using, for example, a transparent glass plate. The light exiting window 5 is attached to a front-end face 12 of the second substrate 4. The front-end face 12 of the second substrate 4 is a cleavage plane formed by cleaving the second substrate 4 by utilizing cleavage characteristics of the second substrate 4. At the front-end face 12 of the second substrate 4, the light guide hole 11 opens. Therefore, the light exiting window 5 is attached to the front-end face 12 of the second substrate 4 in a state of covering the light guide hole 11.

In the light emitting device 1 having the above configuration, light emitted from the light emitting element 2 is incident on the light exiting window 5 through the light guide hole 11 of the second substrate 4, then, the light is transmitted through the light exiting window 5 and allowed to exit to the outside. In this case, since the light emitting element 2 is mounted on the upper surface of the first substrate 3 in the lateral posture, a light ray of the light emitting element 2 is emitted in parallel with the upper surface (surface on which the light emitting element 2 is supported) of the first substrate 3.

In the light emitting device 1 according to the first embodiment, the light emitting element 2 is mounted on the first substrate 3 and the second substrate 4 forms the sealing space 9 between the first substrate 3 and the second substrate 4 by the existence of the concave portion 8. Therefore, the package size can be made smaller than the well-known CAN package. Furthermore, the light emitting element 2 is mounted on the first substrate 3 in the lateral posture, therefore, the thickness (height) of the package can be suppressed to be low. Accordingly, the further size reduction of the package can be realized. Additionally, the front-end face 12 of the second substrate 4 is the cleavage plane, and the light exiting window 5 is attached to the front-end face 12 of the second substrate 4 by using the cleavage plane as the window attaching surface. In this case, the surface accuracy (particularly, flatness) of the window attaching surface will be extremely high. Therefore, when the light exiting window 5 is attached by using, for example, solder as the adhesive, unevenness in thickness due to surface tension of the solder can be suppressed. As a result, it is possible to prevent generation of a gap after the solder is solidified as well as to secure high hermeticity. Also, as the surface accuracy of the window attaching surface is increased, the wafer fusion method can be used for attaching the light exiting window 5. In the wafer fusion method, it is possible to secure high hermeticity without using an adhesive such as solder.

Subsequently, a method of manufacturing the light emitting device according to the first embodiment of the invention will be explained. FIG. 2 is a process flowchart showing a manufacturing procedure of the light emitting device according to the first embodiment of the invention. The manufacturing of the light emitting device is performed largely through processes F1 to F9. Process F1 is an element mounting process. Process F2 is a first cutting process. Process F3 is a wire bonding process. Process F4 is a substrate processing process. Process F5 is a substrate bonding process. Process F6 is a cleaving process. Process F7 is a drilling process. Process F8 is a window attaching process. Process F9 is a second cutting process.

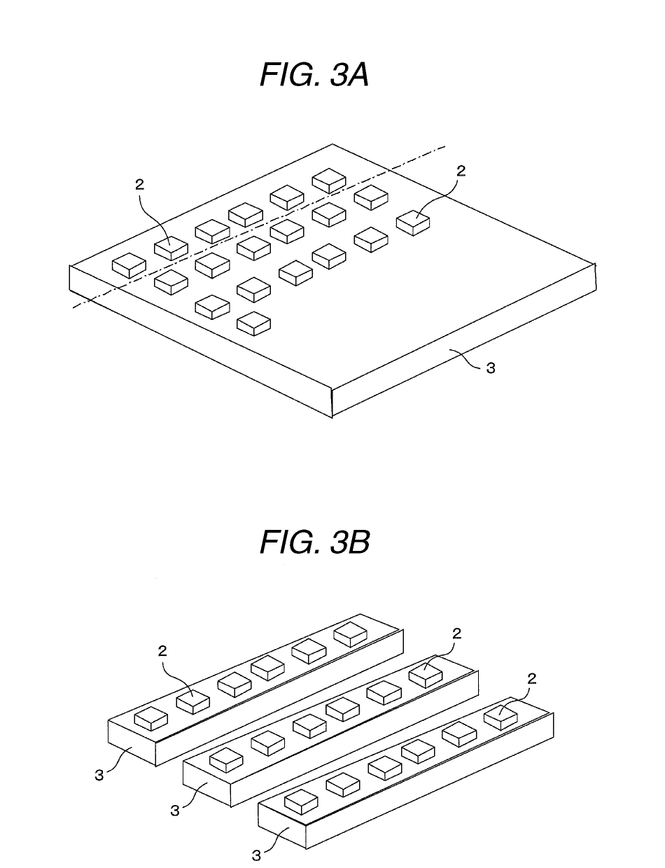

In the element mounting process F1, plural light emitting elements 2 are mounted (chip mount) on the first substrate 3 which is a rectangular substrate having a large diameter in a matrix-state arrangement as shown in FIG. 3A. In this case, the above-described vias 6, the electrode portions 7 and the bonding pads (not shown) are formed in the first substrate 3 in advance. As the first substrate 3, the AlN substrate is used.

In the first cutting process F2, the first substrate 3 on which plural light emitting elements 2 are mounted in the element mounting process F1 is cut into strips (bar shape) as shown in FIG. 3B. According to this, for example, when the total m×n pieces of light emitting elements 2 are mounted on the first substrate 3 in an arrangement of m-rows×n-columns (both “m” and “n” are natural numbers of 2 or more) in the above element mounting process F1, after that, the first substrate 3 is cut into strips by the row in the first cutting process F2, then, a single first substrate 3 which has been cut into the strip will be in a state in which n-pieces of light emitting elements 2 are mounted.

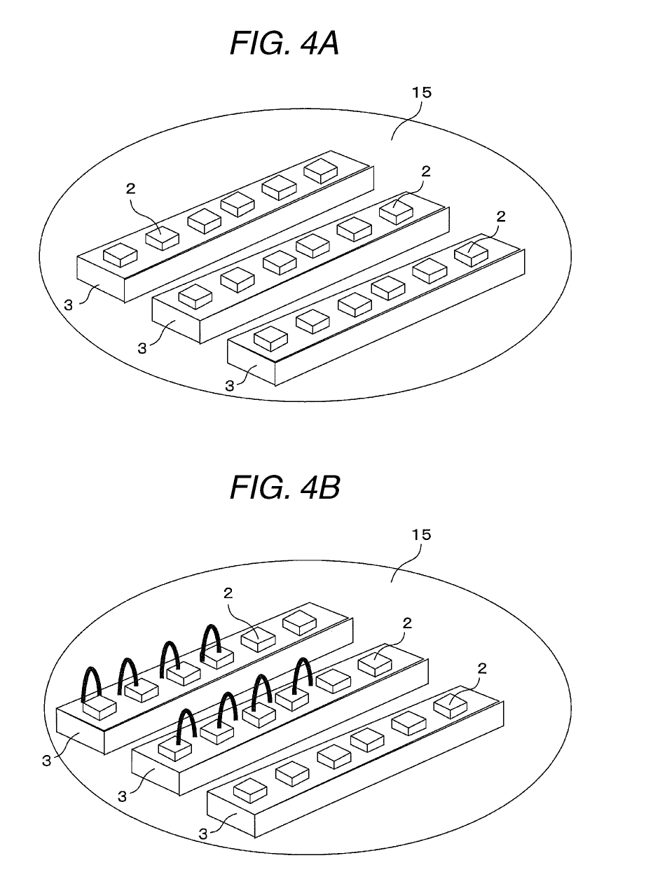

In the wire bonding process F3, respective first substrates 3 cut into the strips are aligned on an alignment substrate 15 as shown in FIG. 4A and respective light emitting elements 2 are electrically connected to the first substrates 3 in the aligned state by wire bonding. On the alignment substrate 15, respective first substrates 3 are aligned in parallel direction to one another as well as the first substrates 3 are held in a fixed state by electrostatic suction and the like. The wire bonding is performed in this state, thereby respective light emitting elements 2 mounted on the first substrate 3 will be in a state of being electrically connected to the first substrates 3 through the wires 10 as shown in FIG. 4B. The wire bonding may be performed in a stage before the first substrate 3 is cut into the strips. In the case that cutting of the first substrate 3 is performed in a state that the wires 10 are connected, there is a fear that the wires are broken at the time of cutting the substrate, therefore, it is desirable to perform wire bonding after the cutting.

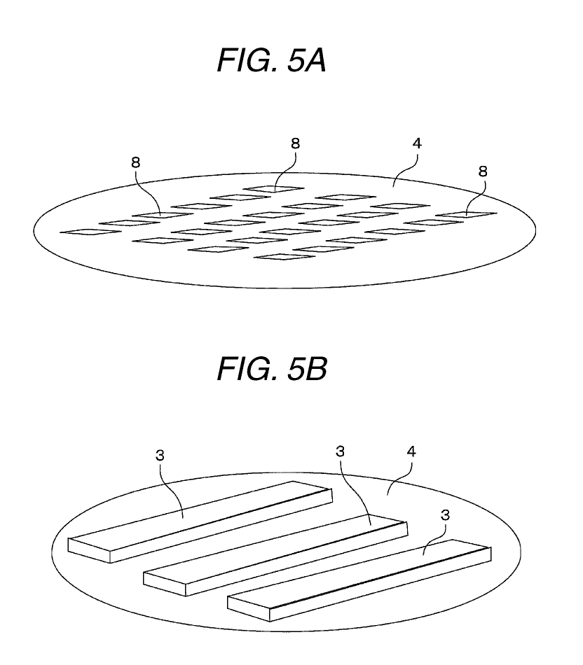

In the substrate processing process F4, plural concave portions 8 are formed on the second substrate 4 having cleavage characteristics as shown in FIG. 5A. As the second substrate 4, a silicon substrate used as a semiconductor wafer is applied. In this case, plural concave portions 8 are formed on the second substrate 4 in a one-to-one correspondence with the plural (m×n) light emitting elements 2. The formation of the concave portions 8 can be performed by, for example, the following method. First, a mask is formed on one surface of the second substrate 4 by a photolithography method, and the one surface of the second substrate 4 is etched (dry etching or wet etching) through the mask. In this method, the concave portions 8 are formed by etching at portions where are not shielded by the mask. The depth size of the concave portions 8 formed by the etching is made to be smaller than the plate thickness size of the second substrate 4 under a condition that at least the light emitting element 2 and the wire 10 can be housed in the sealing space 9.

In the substrate bonding process F5, plural first substrates 3 having strip shapes are bonded to the second substrate 4 in a state in which the light emitted elements 2 and the concave portions 8 which correspond to each other are positioned as shown in FIG. 5B. In this case, the light emitting elements 2 mounted on the first substrate 3 are housed in the concave portions 8 formed in the second substrate 4 so as to correspond to the light emitting elements 2. The first substrate 3 and the second substrate 4 are bonded by using, for example, the wafer fusion method or the solder material. It is preferable that plasma cleaning using, for example, argon gas is performed before the bonding.

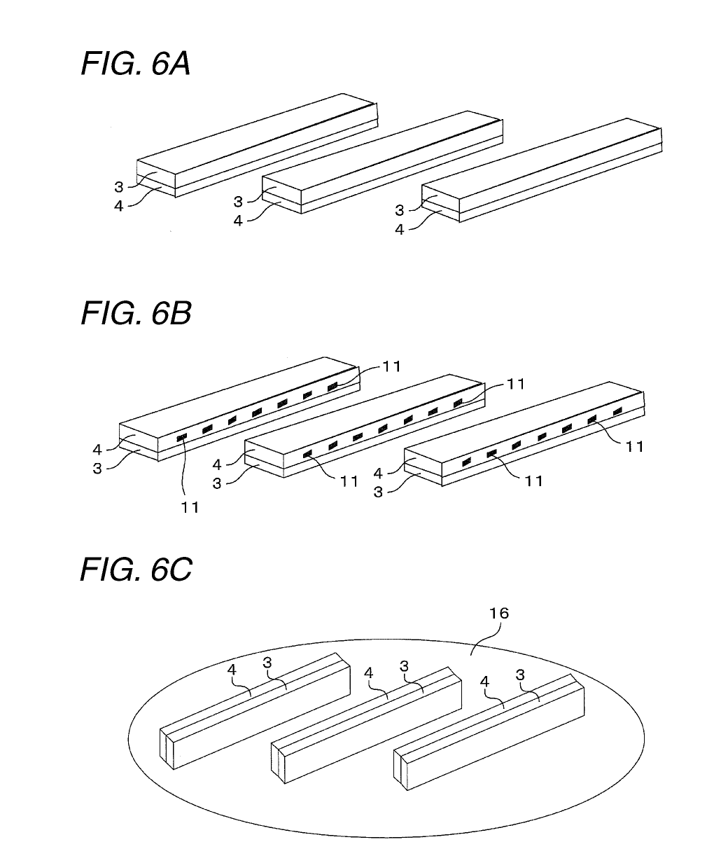

In the cleaving process F6, the second substrate 4 is cleft by using cleavage characteristics of the silicon substrate used as the second substrate 4. Specifically, dividing lines are formed in the second substrate 4 along the longitudinal direction of the first substrates 3 by marking and the like, and the second substrate 4 is cleft at positions of the divided lines. Accordingly, a bonded substrate (3, 4) formed by bonding the first substrate 3 and the second substrate 4 are separated into the strips as shown in FIG. 6A.

At that time, the cleaving of the second substrate 4 is performed so that at least the surface to which the light exiting window 5 is attached (front-end face 12) is a cleavage plane. In the second substrate 4, it is not always necessary that the surface which is the opposite side of the surface to which the light exiting window 5 is attached is the cleavage plane. Accordingly, the opposite side of the surface to which the light exiting window is attached can be cut by a dicer. When the surface which is the opposite side of the surface to which the light exiting window 5 is attached is the cleavage plane, parallelism between the front-end face 12 of the second substrate 4 and a back-end face thereof will be extremely high. Therefore, the light exiting window 5 can be uniformly pressed on the front-end face 12 of the second substrate 4 when the light exiting window 5 is attached, which is advantageous. In addition to the first substrate 3, the second substrate 4 are not separated into individual pieces but are into strips, which makes the substrate easy to be handled in later processes.

In the drilling process F7, the light guide holes 11 are formed on the front-end face 12 of the second substrates 4 which have been cut into strips through the cleaving process F6 as shown in FIG. 6B. The formation of the light guide holes 11 is performed by using, for example, a Deep RIE (Reactive Ion Etching) method. The light guide holes 11 are formed so as to be connected to the concave portions 8 by drilling processing due to the Deep RIE method. Additionally, the light guide holes 11 are formed in the longitudinal direction of the bonding substrate (3, 4) having the strip shape at the same intervals as the light emitting elements 2. Accordingly, the light guide holes 11 are formed in a one-to-one correspondence with the light emitting elements 2.

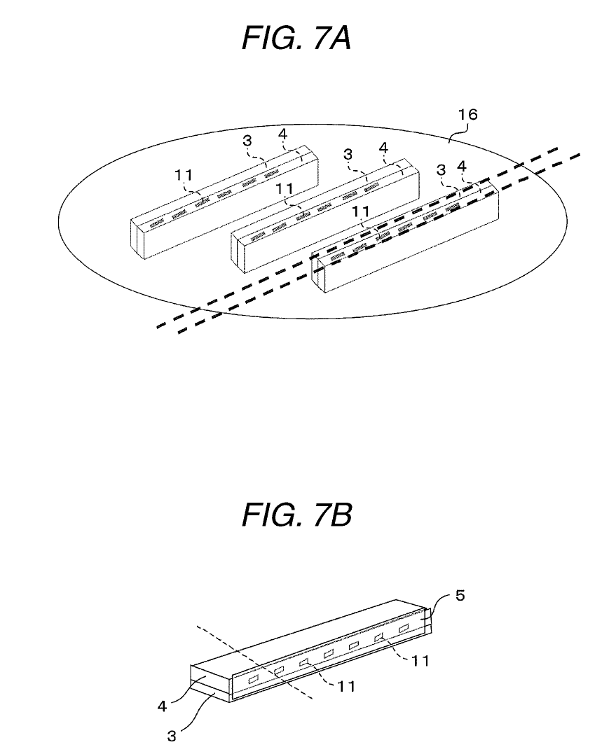

In the window attaching process F8, the second substrate 4 and a transparent flat glass-plate 16 having a circular shape are bonded to each other in a state in which the front-face end 12 (surface in which the light guide holes 11 open) of the second substrate 4 abuts on one surface of the glass plate 16 as shown in FIG. 6C. On the glass substrate 16, plural bonded substrates (3, 4) are arranged in lines. Furthermore, in the window attaching process F8, the glass substrate 16 is cut by the dicer by each bonded substrate (3, 4) as shown in FIG. 7A.

When the glass substrate 16 and the second substrate 4 are bonded, the front-end face 12 of the second substrate 4 is the cleavage plane, therefore, the surface accuracy (particularly, flatness) at that part is extremely high. Accordingly, for example, when the second substrate 4 is bonded to one surface of the glass substrate 16 by using the solder material, high hermitic sealing performance can be secured by suppressing unevenness in thickness of the solder material due to effects of surface tension. In addition, the surface accuracy will be extremely high, thereby bonding the second substrate 4 to the glass plate 16 by using the wafer fusion method whereby high hermetic sealing performance can be obtained.

At the time of performing the bonding between the glass plate 16 and the second substrate 4, an optical film such as SiO2, MgF2, Al2N3 and the like optical reflectivity of which is designed is provided on the glass plate 16 to be the light exiting window 5, which increases the transmittance and reduces returned light, as a result, measures for noise generation can be taken. In the case that the top surface is SiO2, there is an advantage that bonding force can be increased when performing plasma cleaning before the bonding. As a further preferable method, first, the bonded substrates of the first substrate 3 and the second substrate 4 are aligned on an alignment substrate which is not shown. Next, positioning between respective bonded substrates (3, 4) aligned on the alignment substrate and the glass plate 16 is performed and both are temporarily bonded by contact, weight application and heating. Next, the bonded substrates (3, 4) and the glass plate 16 are finally bonded by further weight application and heating. At that time, when the variations of length of the bonded substrates (3, 4) in the optical axis direction are wide, it is preferable that weight is applied by the individual bonded substrate (by the bar). Particularly, when the back-end face of the second substrate 4 is the cleavage plane, the parallelism between the front-face surface 12 and the back-end face of the second substrate 4 is secured, it is advantageous when weight is applied by the bar.

In the second cutting process F9, the strip-shaped bonded portion (3, 4) is cut into individual pieces with the glass substrate 16 by the dicer as shown in FIG. 7B. At this time, the glass substrate 16 is cut as the light exiting window 5. According to this, the light emitting device 1 shown in FIG. 1 is obtained.

In the manufacturing method of the light emitting device according to the first embodiment of the invention, after plural light emitting elements 2 are mounted on the first substrate 3, the first substrates 3 and the second substrate 4 are bonded to each other so that the light emitting elements 2 are housed in the concave portions 8, thereby forming small packages. Additionally, after the second substrate 4 is cleft, the light exiting window 5 is attached to the cleavage plane, thereby sealing the light emitting elements 2 housed in the concave potions 8 with high hermeticity. As a result, it is possible to obtain the light emitting device in which the light emitting element is sealed with high hermeticity though it is a small package.

Also in the method of manufacturing the light emitting device according to the first embodiment of the invention, m×n pieces of light emitting elements 2 are mounted at the same time on the first substrate 3 having a large diameter, after that, the substrate bonding process F5 to the window attaching process F8 can be performed by batch processing, taking the first substrate 3 which is cut into a strip so as to include n-pieces of light emitting element 2 as one unit. Accordingly, it is possible to manufacture the light emitting device 1 with high productivity.

### Second Embodiment

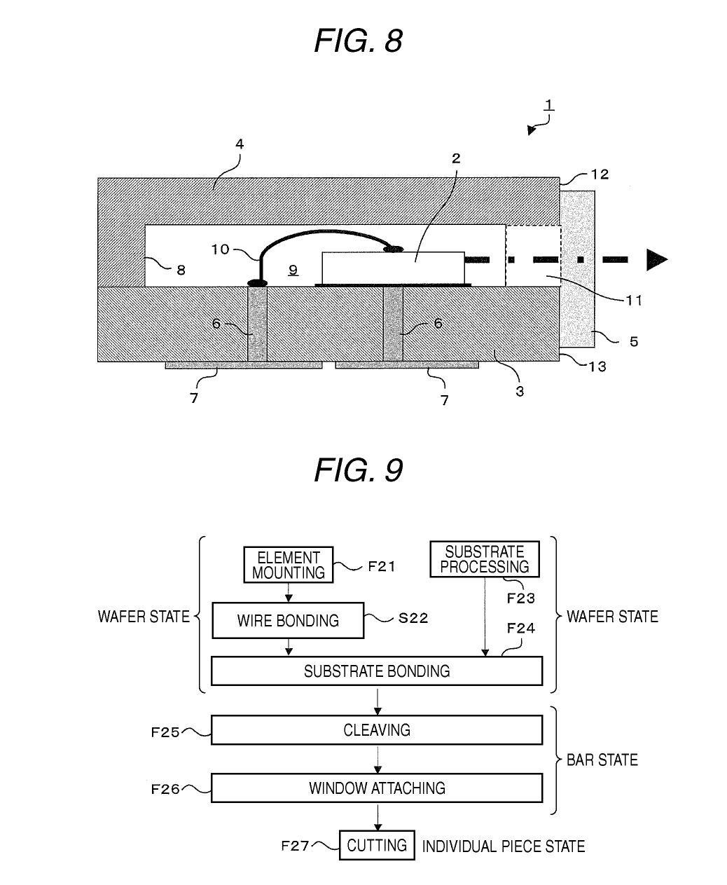

FIG. 8 is a sectional side view showing a configuration of a light emitting device according to a second embodiment of the invention. In the second embodiment of the invention, explanation will be made by putting the same numerals on corresponding components cited in the first embodiment. The shown light emitting device 1 largely includes the light emitting element 2, the first substrate 3, the second substrate 4 and the light exiting window 5, which is the same as the first embodiment in this point. However, the second embodiment is different from the first embodiment in the following points.

Specifically, in the first embodiment, the first substrate 3 is formed by using an AlN substrate not having cleavage characteristics. On the other hand, in the second embodiment, the first substrate 3 is formed by using a silicon substrate having cleavage characteristics. According to this, in the second embodiment, both the first substrate 3 and the second substrate 4 are formed by using the silicon substrate including cleavage characteristics.

In the first embodiment, the front-end face 12 of the second substrate 4 is the cleavage plane and the light exiting window 5 is attached to the front-end face 12 of the second substrate 4 by using the cleavage plane as the window attaching surface. On the other hand, in the second embodiment, a front-end face 13 of the first substrate 3 and the front-end face 12 of the second substrate 4 are made to be cleavage planes respectively, and the light exiting window 5 is attached to the front-end face 13 of the first substrate 3 and the front-end face 12 of the second substrate 4 by using the cleavage planes as the window attaching surfaces. Plane directions (plane directions of the cleavage planes) of the front-end faces 12, 13 of respective substrates 3, 4 are the same.

The light exiting window 5 is attached in a state of covering the light guide hole 11 which opens at the front-end face 12 of the second substrate 4. It is preferable that the light guide hole 11 is formed in the second substrate 4 in the same manner as the first embodiment or also preferable that it is formed in a state in which the first substrate 3 and the second substrate 4 are connected. The front-end face 13 of the first substrate 3 and the front-end face 12 of the second substrate 4 are flush with each other. The first substrate 3 and the second substrate 4 have the same outline dimension when seen two-dimensionally.

In the light emitting device 1 having the above configuration, light emitted from the light emitting element 2 is incident on the light exiting window 5 through the light guide hole 11 of the second substrate 4, then, the light is transmitted through the light exiting window 5 and allowed to exit to the outside. In this case, the light emitting element 2 is mounted on the upper surface of the first substrate 3 in the lateral posture, therefore, a light ray from the light emitting element 2 is emitted in parallel with the upper surface of the first substrate 3 (surface on which the light emitting element 2 is supported).

In the light emitting device 1 according to the second embodiment of the invention, the light emitting element 2 is mounted on the first substrate 3 and the second substrate 4 forms the sealing space 9 between the first substrate 3 and the second substrate 4 by the existence of the concave portion 8 in the same manner as the first embodiment. Accordingly, the package size can be made smaller than the well-known CAN package. Furthermore, since the light emitting element 2 is mounted on the first substrate 3 in the lateral posture, the thickness (height) of the package can be suppressed to be low. Accordingly, further size reduction of the package can be realized. Additionally, the front-end face 12 of the second substrate 4 is the cleavage plane and the light exiting window 5 is attached to the front-end face 12 of the second substrate 4 by using the cleavage plane as the window attaching surface. In this case, the surface accuracy (particularly, flatness) of the window attaching surface is extremely high. Accordingly, when the light exiting window 5 is attached by using, for example, solder as an adhesive, the thickness unevenness due to surface tension of the solder can be suppressed. Therefore, it is possible to prevent generation of a gap after the solder is solidified and to secure the high hermeticity. As the surface accuracy of the window attaching surface becomes high, the wafer fusion method can be used for attaching the light exiting window 5. In the wafer fusion method, it is possible to secure high hermeticity without using an adhesive such as solder.

Furthermore, in the light emitting device 1 according to the second embodiment, the first substrate 3 and the second substrate 4 are made of the same material (silicon in the embodiment), therefore, stress caused by the difference between thermal expansion coefficients can be reduced. Additionally, when the substrate materials are the same kind, stress at the connection interface caused by lattice mismatch can be reduced and a good cleavage plane can be obtained in the cleavage, which is desirable. Since the light exiting window 5 is attached to both the front-end face 13 of the first substrate 3 and the front-end face 12 of the second substrate 4, it is possible to secure a joint surface of the light exiting window 5 wider as compared with the first embodiment. Accordingly, the sealing by attaching the light exiting window 5 becomes easy. Though not shown, when concave portions are formed also in the first substrate 3 in the same manner as in the second substrate 4, a diameter of the light guide hole can be taken larger. Accordingly, the area in which shading of light due to the first substrate and the second substrate is not generated can be taken larger, therefore, the degree of freedom at the time of deciding arrangement of the light emitting elements 2 in the optical axis direction is increased.

Subsequently, a method of manufacturing the light emitting device according to the second embodiment of the invention will be explained. FIG. 9 is a process flowchart showing a manufacturing procedure of the light emitting device according to the second embodiment. The manufacturing of the light emitting device is performed largely through Process F21 to F27. Process F21 is an element mounting process. Process F22 is a wire bonding process. Process F23 is a substrate processing process. Process F24 is a substrate bonding process. Process F25 is a cleaving process. Process F26 is a window attaching process. Process F27 is a cutting process.

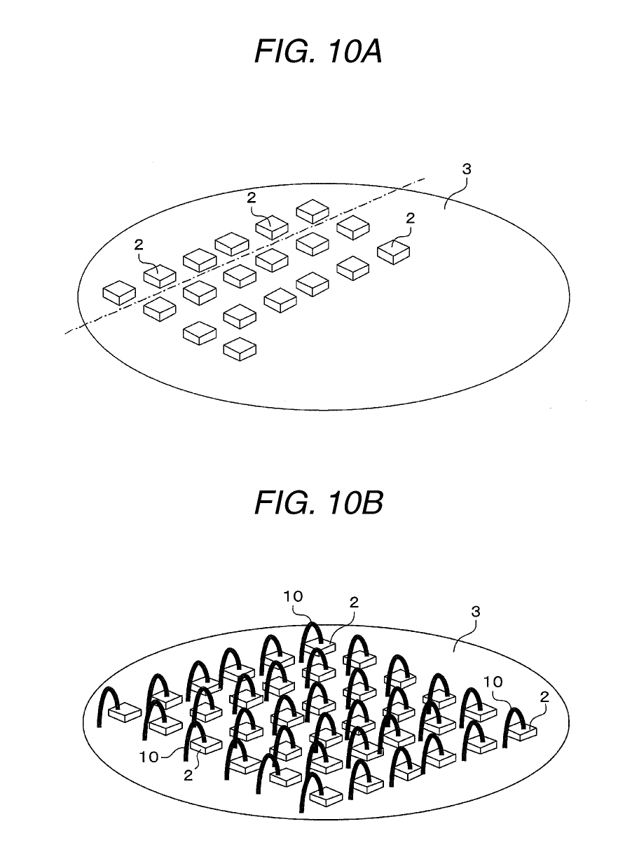

In the element mounting process F21, plural light emitting elements 2 are mounted (chip mount) on a circular first substrate 3 having cleavage characteristics in a matrix-state arrangement as shown in FIG. 10A. In this case, vias 6, electrode portions 7 and bonding pads (not shown) are formed on the first substrate 3 in advance. As the first substrate 3, a silicon substrate (silicon wafer) used as the semiconductor wafer is used. On the first substrate 3, m×n pieces of light emitting elements 2 are mounted.

In the wire bonding process F22, respective elements 2 mounted on the first substrate 3 are electrically connected to the first substrate 3 by wire bonding. Accordingly, respective light emitting elements 2 mounted on the first substrate 3 are electrically connected to the first substrate 3 through wires 10 as shown in FIG. 10B.

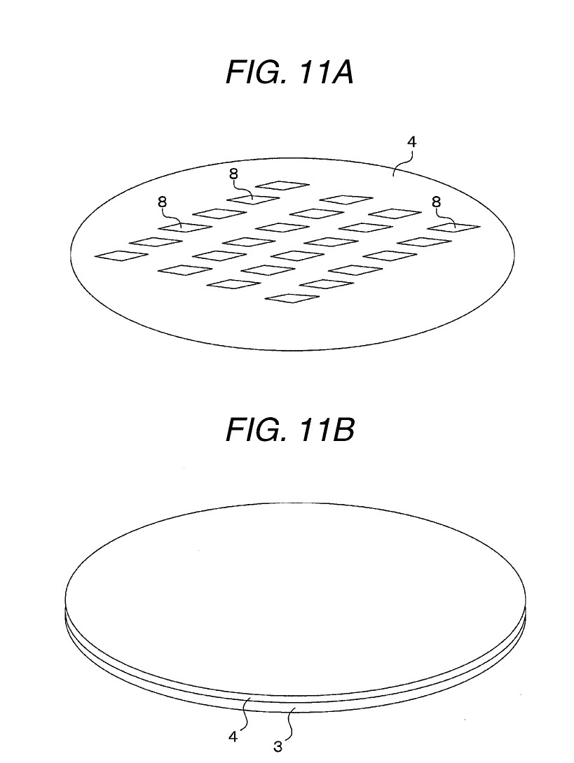

In the substrate processing process F23, plural concave portions 8 are formed on the circular second substrate 4 having cleavage characteristics as shown in FIG. 11A. As the second substrate 4, the silicon substrate (silicon wafer) used as the semiconductor wafer is used. The formation of the concave portions 8 can be performed by, for example, the same method as the first embodiment. The formation is performed by, first, forming a mask on one surface of the second substrate 4 by a photolithography method and etching (dry etching or wet etching) one surface of the second substrate 4 through the mask. In this method, the concave portions 8 are formed by etching at portions not shielded by the mask. The depth size of the concave portions 8 formed by the etching is smaller than the plate thickness size of the second substrate 4 under a condition that at least the light emitting element 2 and the wire 10 can be housed in the sealing space 9.

The substrate bonding process F24, the first substrate 3 on which plural light emitting elements 2 are mounted in the element mounting process F21 and the second substrate 4 in which plural concave portions 8 are formed in the substrate processing process F23 are bonded to each other in a state in which the light emitting elements 2 and the concave portions 8 which correspond to each other are positioned as shown in FIG. 11B. In this case, the light emitting elements 2 mounted on the first substrate 3 are housed in the concave portions 8 formed in the second substrate 4 so as to correspond to the light emitting elements 2. The first substrate 3 and the second substrate 4 are bonded by, for example, using wafer fusion method or by using the solder material in the same manner as the first embodiment. In this case, batch processing of wafers can be performed, which increases the work efficiency. It is preferable that the plane directions of the cleavage planes of respective substrates 3, 4 are matched because the attaching surfaces of the light exiting window are matched in the substrates 3, 4. In order to perform positioning more accurately than positioning by an orientation flat provided at an outer circumferential portion of each of substrates 3, 4 using the semiconductor wafer, it is attainable by cleaving the respective substrates 3, 4 in advance to expose cleavage planes.

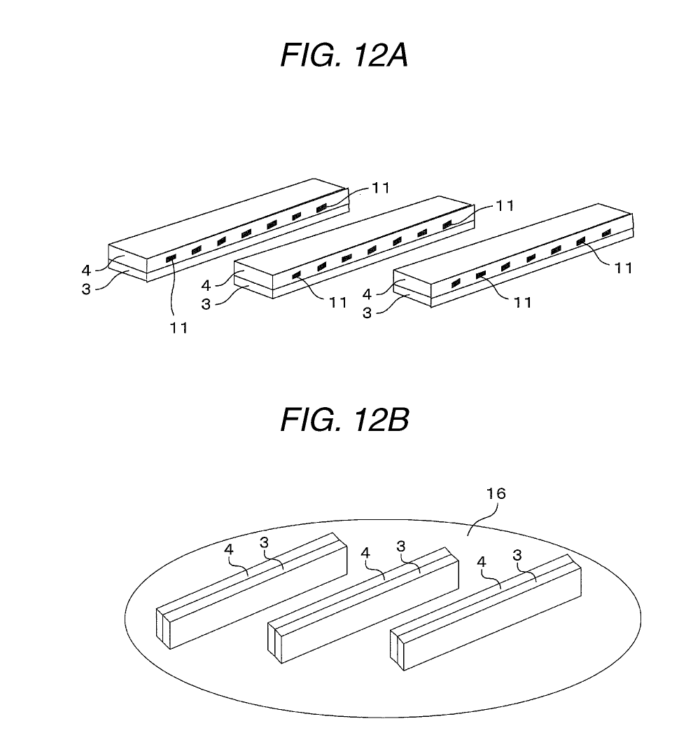

In the cleaving process F25, the first substrate 3 and the second substrate 4 are cleft by using cleavage characteristics of the silicon substrate used as the first substrate 3 and cleavage characteristics of the silicon substrate used as the second substrate 4. Specifically, dividing lines are formed by marking in the first substrate 3 and the second substrate 4 respectively, and the first substrate 3 and the second substrate 4 are cleft at positions of the dividing lines. At this time, respective substrates 3, 4 are cleft straight on the same lines. Accordingly, the bonded substrate (3, 4) of the first substrate 3 and the second substrate 4 are separated into strips as shown in FIG. 12A.

At this time, on a single piece of first substrate 3 cut into a strip with the second substrate 4, n-pieces of light emitting elements 2 are mounted, respectively. When plural light emitting elements 2 are mounted on the first substrate 3 in the element mounting process F21, two light emitting elements are arranged face to face so that light emitting directions face to each other, thereby allowing two light emitting elements 2 to share one cleavage plane, which is desirable. Additionally, it is preferable that the cleavage of the first substrate 3 and the second substrate 4 is performed so that at least surfaces (front-end faces 12, 13) to which the light exiting window 5 is attached are the cleavage planes. In the first substrate 3 and the second substrate 4, it is not always necessary that the surface which is the opposite side of the surface to which the light exiting window 5 is attached is the cleavage plane. Therefore, the opposite side of the surface to which the light exiting window 5 is attached can be cut by the dicer. However, when the surface which is the opposite side of the surface to which the light exiting window 5 is attached is made to be the cleavage plane, the parallelism between the front-end face 13 and the back-end face of the first substrate 3 and the parallelism between the front-end face 12 and the back-end face of the second substrate 4 are extremely high. According to this, the light exiting window 5 can be uniformly pushed on the front-end face 13 of the first substrate 3 and the front-end face 12 of the second substrate 4 when the light exiting window 5 is attached, which is advantageous.

The plural light guide holes 11 provided at the front-end face 12 of the second substrate 4 in each bonded substrates (3, 4) separated into a strip by the cleavage are formed as parts of the concave portions 8 at the same time of forming the plural concave portions 8 in the substrate processing process F23. It is also preferable that the light guide holes 11 are formed, after the cleaving process F25, so as to be connected to the concave portions 8 by drilling processing by, for example, a Deep RIE method and the like. In this case, an advantage that the bonded substrates (3, 4) can be cleft easily can be obtained.

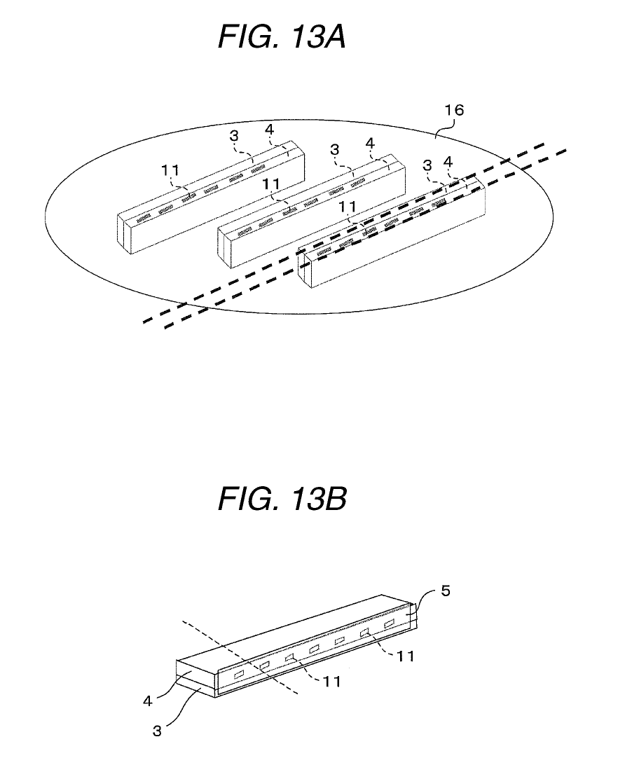

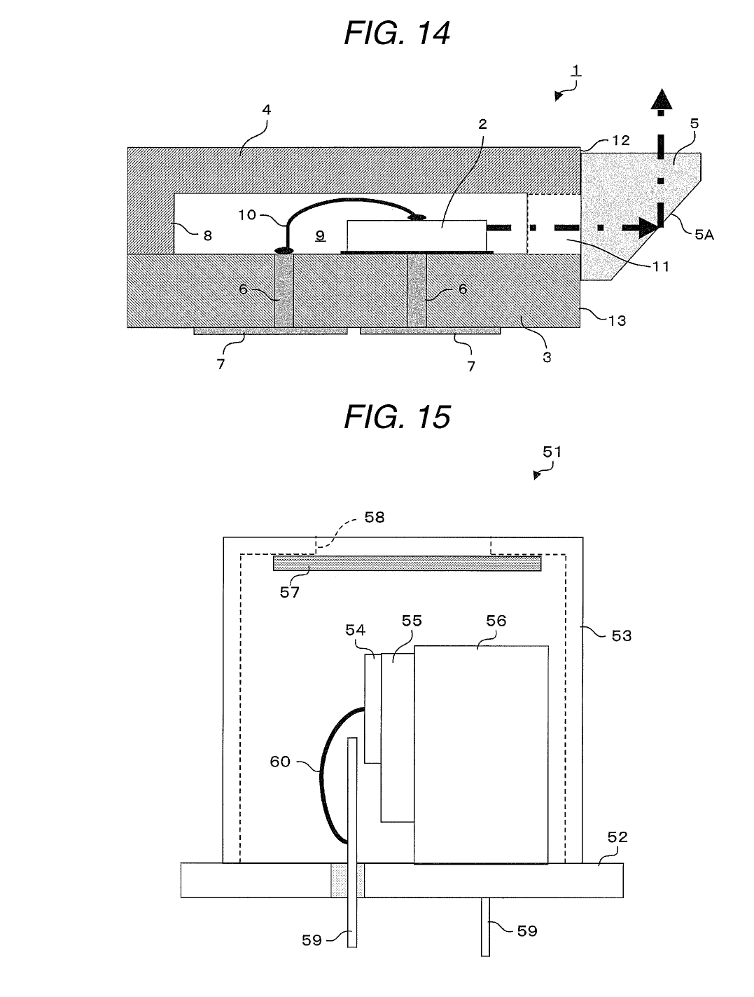

The window attaching process F26, the strip-shaped bonded substrates (3, 4) are bonded to the glass substrate 16 in a state in which both the front-face end 13 of the first substrate 3 and the front-end face 12 of the second substrate 4 abut on one surface of the transparent and flat glass plate 16 having a circular shape as shown in FIG. 12B. It is preferable that an optical film is provided on the glass plate 16 in the same manner as the first embodiment. Plural bonded substrates (3, 4) are arranged in lines on the glass plate 16. Furthermore, in the window attaching process F26, the glass substrate 16 is cut by the dicer by each bonded substrate (3, 4) as shown in FIG. 13A.

When the glass substrate 16 and the bonded substrate (3, 4) are bonded, both the front-end face 13 of the first substrate 3 and the front-end face 12 of the second substrate 4 are the cleavage plane, therefore, the surface accuracy (particularly, flatness) at that parts is extremely high. Accordingly, for example, when the bonded substrate (3, 4) is bonded to one surface of the glass substrate 16 by using the solder material, high hermitic sealing performance can be secured by suppressing unevenness in thickness of the solder material due to effects of surface tension. In addition, the surface accuracy will be extremely high, thereby bonding the bonded substrate (3, 4) to the glass plate 16 by using the wafer fusion method whereby high hermetic sealing performance can be obtained.

In the cutting process F27, the strip-shaped bonded substrate (3, 4) is cut into individual pieces with the glass plate 16 by the dicer as shown in FIG. 13B. At this time, the glass plate 16 is cut as the light exiting window 5. Accordingly, the light emitting device 1 shown in FIG. 8 can be obtained.

In the method of manufacturing the light emitting device according to the second embodiment of the invention, after the plural light emitting elements 2 are mounted on the first substrate 3, the first substrate 3 and the second substrate 4 are bonded to each other so as to house the light emitting elements 2 in the concave portions 8, thereby forming small-sized packages in the same manner as the first embodiment. Also, after the first substrate 3 and the second substrate 4 are respectively cleft, the light exiting window 5 is attached to the cleavage planes, thereby sealing the light emitting elements 2 housed in the concave portions 8 with high hermeticity. Accordingly, the light emitting device in which the light emitting element is sealed with high hermeticity though the package is small.

In the method of manufacturing the light emitting device according to the second embodiment, m×n pieces of light emitting elements 2 are mounted on the first substrate 3 having the large diameter at the same time as well as the substrate bonding process F24 is performed by the wafer, after that, the cleaving process F25 to the window attaching process F26 can be performed by batch processing, taking the bonded substrate (3, 4) which is cut into a strip so as to include n-pieces of light emitting element 2 as one unit. Accordingly, it is possible to manufacture the light emitting device 1 with high productivity. Furthermore, since the wire bonding with respect to respective light emitting elements 2 and the bonding of substrates 3, 4 are performed in the wafer state, further improvement of productivity can be expected.

Note that the light exiting window 5 is formed by not only the flat-glass plate which merely transmits light from the light emitting element 2 but also by a prism including a reflective surface 5A having an inclination of 45 degrees with respect to the optical axis of light emitted from the light emitting element 2 as shown, for example, in FIG. 14. In such configuration, light from the light emitting element 2 is reflected at the reflective surface 5A of the light exiting window 5 at a right angle. Accordingly, light from the light emitting element 2 can be allowed to exit upward (in the vertical direction) though the light emitting element 2 is mounted in the lateral posture. Therefore, a quasi-surface emitting function can be realized. The point that the light exiting window 5 is formed by the prism including the reflective surface 5A can be also applied to the first embodiment.

In the first embodiment, AlN is used for the first substrate 3 and Si is used for the second substrate 4 as base materials for substrates, and in the second embodiment, Si is used for both the first substrate 3 and the second substrate 4, however, materials for substrates can be variously changed. Particularly, concerning the substrate including the window attaching surface, any of materials of, for example, GaAs (gallium/arsenic), GaP (gallium/phosphorous), InP (indium/phosphorous), GaN (gallium nitride) is used in addition to the above Si, AlN, thereby forming the light emitting device 1 inexpensively.

In the first embodiment and the second embodiment, the light emitting elements 2 are directly mounted on the first substrate 3, however, the invention is not limited to this, and for example, the light emitting elements 2 are mounted on the first substrate 3 through a not-shown submount.

In the first embodiment, the substrate having cleavage characteristics is used only as the second substrate 4, and in the second embodiment, the substrate having cleavage characteristics is used as both the first substrate 3 and the second substrate 4, however, the invention is not limited to this, and it is possible to use the substrate having cleavage characteristics only as the first substrate 3. Specifically, concave portions for housing elements are formed in the first substrate 3 by processing the substrate as well as light guide holes connecting to the concave portions are formed, and the light exiting window is attached to the surface on which the light guide holes open as a cleavage plane (window attaching surface).

The present application contains subject matter related to that disclosed in Japanese Patent Priority Application JP 2008-137472 filed in the Japan Patent Office on May 27, 2008, the entire contents of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A light emitting device comprising:
a light emitting element emitting light;
a first substrate on which the light emitting element is mounted;
a second substrate forming a sealing space for the light emitting element between the first substrate and the second substrate; and
a light exiting window for allowing light emitted from the light emitting element to exit,
wherein at least one of the first substrate and the second substrate has a cleavage characteristic and a cleavage surface there of serves as a window attaching surface to which the light exiting window is attached.

2. The light emitting device according to claim 1,
wherein the light emitting element is mounted in a lateral posture.

3. The light emitting device according to claim 1,
wherein the substrate including the window attaching surface is made of any of materials of Si, GaAs, GaP, InP, AlN and GaN.

4. The light emitting device according to claim 1,
wherein the light exiting window has a reflective surface reflecting light emitted from the light emitting element at a right angle.

5. A method of manufacturing a light emitting device comprising the steps of:
mounting plural light emitting elements on a first substrate;
forming plural concave portions on a second substrate so as to correspond to mounting positions of the plural light emitting elements to be mounted on the first substrate;
bonding the first substrate to the second substrate so as to house the light emitting elements in the concave portions;
cleaving at least one of the first substrate and the second substrate; and
attaching a light exiting window on a cleavage plane of at least one substrate in a state of covering light guide holes opening at the cleavage plane.

6. The method of manufacturing the light emitting device according to claim 5, further comprising the step of:
cutting the first substrate on which the plural light emitting elements are mounted into strips, and
wherein the second substrate is cleft along the longitudinal direction of the first substrates cut into strips.

7. The method of manufacturing the light emitting device according to claim 6, further comprising the step of:
connecting the first substrate to the light emitting elements electrically by wire bonding after the first substrate is cut into strips.

8. The method of manufacturing the light emitting device according to claim 5,
wherein, after the first substrate and the second substrate are bonded to each other, the bonded substrate of the first substrate and the second substrate are cleft into strips, then, the light exiting window is attached to the cleavage plane of the bonded substrate in a state of covering the light guide holes opening at the cleavage plane.

9. The method of manufacturing the light emitting device according to claim 8,
wherein the first substrate and the light emitting elements are electrically connected by wire bonding after the plural light emitting elements are mounted on the first substrate as well as before the first substrate and the second substrate are bonded to each other.

10. The method of manufacturing the light emitting device according to claim 5,
wherein the light guide hole is formed as part of the concave portion when the concave portions are formed in the second substrate.
